(19) United States
(12) Patent Application Publication
(10) Pub. No.: US 2019/0148615 A1
(43) Pub. Date: May 16, 2019

(54) VERTICAL NANOWIRE THERMOELECTRIC DEVICE INCLUDING SILICIDE LAYER AND METHOD OF MANUFACTURING THE SAME

(71) Applicant: POSTECH ACADEMY-INDUSTRY FOUNDATION, Pohang-si (KR)

(72) Inventors: Chang Ki BAEK, Pohang-si (KR); Ki Hyun Kim, Pohang-si (KR); Seung Ho Lee, Daejeon (KR)

(21) Appl. No.: 16/186,844

(22) Filed: Nov. 12, 2018

(30) Foreign Application Priority Data
Nov. 16, 2017 (KR) 10-2017-0153007

(51) Int. Cl. H01L 35/30; H01L 29/06; H01L 35/22

(52) U.S. Cl. CPC H01L 35/30; H01L 35/22; H01L 29/0673

(57) ABSTRACT

The present invention relates to a vertical nanowire thermoelectric device which includes a heat emitting portion, a substrate disposed on the heat emitting portion and including doping regions having a first n-type doping region, a first p-type doping region, a second n-type doping region, and a second p-type doping region which are arranged to be spaced apart from each other, vertical nanowire arrays including a first n-type nanowire array, a first p-type nanowire array, a second n-type nanowire array, and a second p-type nanowire array which are formed on the first n-type doping region, the first p-type doping region, the second n-type doping region, and the second p-type doping region, respectively, a lower silicide layer formed in the doping regions and a connection region which connects the first p-type doping region and the second n-type doping region, an upper silicide layer formed on the vertical nanowire arrays, a first upper electrode configured to electrically connect an upper end of the first n-type nanowire array to an upper end of the first p-type nanowire array, and a second upper electrode configured to electrically connect an upper end of the second n-type nanowire array to an upper end of the second p-type nanowire array.

### CLAIM FOR PRIORITY

This application claims priority to Korean Patent Application No. 10-2017-0153007 filed on Nov. 16, 2017 in the Korean Intellectual Property Office (KIPO), the entire contents of which are hereby incorporated by reference.

### BACKGROUND

### 1. Technical Field

Example embodiments of the present invention relate to a thermoelectric device, and more specifically, to a vertical silicon nanowire thermoelectric device including a silicide layer, and a method of manufacturing the same.

### 2. Related Art

Due to the climate agreement negotiated in Paris, France by countries around the world in December 2015, there is a growing interest in the development of renewable energy and energy efficiency improvement technologies worldwide in order to reduce greenhouse-gas-emission. Among various technologies, energy harvesting technology, which produces electric energy using abandoned energy, has entered the spotlight as a promising technology. Thermoelectric devices are energy harvesting devices that have a Seebeck effect that directly converts thermal energy into electrical energy. Since 50% of energy used in the era when fossil fuels are used as a primary energy source is released and discarded in the form of heat, the thermoelectric devices can be used in various fields such as industrial, automobile, aerospace, aviation, nautical, wearable devices, and the like.

Bi₂Te₃ is a widely used as a thermoelectric material because of its high thermoelectric conversion efficiency. However, Bi₂Te₃ is a material that is low in reserves on earth, is expensive, and harmful to the human body. Therefore, Bi₂Te₃ has low economic efficiency and many restrictions on commercialization. In addition, mass production of devices is difficult because the devices should be manufactured using a hot press molding technique. On the other hand, silicon has high economic efficiency because of its abundant reserves and low material cost. It is possible to manufacture devices using semiconductor processing technology which has been used for several decades in the semiconductor industry so mass production of devices is simple. However, the silicon has not entered the spotlight as a commercial material because a thermoelectric conversion characteristic thereof is as low as a level of 1/100th of that of Bi₂Te₃ due to high thermal conductivity. The thermoelectric conversion characteristic is inversely proportional to the thermal conductivity and is proportional to the electrical conductivity.

Recently, it has been reported that when silicon is manufactured into a one-dimensional nanowire structure, scattering occurs frequently while phonons pass through nanowires, thereby decreasing the thermal conductivity and improving the thermoelectric conversion characteristic. As a result, interest in silicon nanowire thermoelectric devices is increasing. However, since the thermoelectric conversion characteristics of silicon nanowires are still low compared to Bi₂Te₃, studies on a structure and process for improving the thermoelectric conversion characteristics as a result of lowering the thermal conductivity are being actively conducted by maximizing a phonon scattering effect of a silicon nanowire thermoelectric device.

### DOCUMENT OF RELATED ART

### [Patent Document]

Korean Patent Application Publication No. 10-2012-0077487

### SUMMARY

Accordingly, example embodiments of the present invention are provided to substantially obviate one or more problems due to limitations and disadvantages of the related art.

Example embodiments of the present invention provide a silicon nanowire thermoelectric device including a silicide layer, which has improved thermoelectric conversion efficiency and an increased amount of output.

Example embodiments of the present invention also provide a method of manufacturing a silicon nanowire thermoelectric device including a silicide layer, of which mass production is achievable using a silicon semiconductor process.

In some example embodiments, a vertical nanowire thermoelectric device includes a heat emitting portion, a substrate disposed on the heat emitting portion and including doping regions having a first n-type doping region, a first p-type doping region, a second n-type doping region, and a second p-type doping region which are arranged to be spaced apart from each other, vertical nanowire arrays including a first n-type nanowire array, a first p-type nanowire array, a second n-type nanowire array, and a second p-type nanowire array which are formed on the first n-type doping region, the first p-type doping region, the second n-type doping region, and the second p-type doping region, respectively, a lower silicide layer formed in the doping regions and a connection region which connects the first p-type doping region and the second n-type doping region, an upper silicide layer formed on the vertical nanowire arrays, a first upper electrode configured to electrically connect an upper end of the first n-type nanowire array to an upper end of the first p-type nanowire array, and a second upper electrode configured to electrically connect an upper end of the second n-type nanowire array to an upper end of the second p-type nanowire array.

The vertical nanowire thermoelectric device may further include a thermal protective film formed on the substrate and configured to fill spaces between the vertical nanowire arrays.

The thermal protective film may be made of at least one of SiO₂, SiN, SOG, borophosphosilicate glass (BPSG), and polyimide.

The vertical nanowire arrays may include nanowires having a shape in which a cross section is constant from top to bottom. For example, the nanowires may have a constant shape and area of cross section from to bottom. The vertical nanowire arrays may have nanowires having inclined side surfaces because cross-sectional areas of upper portions of the nanowires are greater or smaller than cross-sectional areas of lower portions of the nanowires. Cross-sectional areas of nanowires of the vertical nanowire arrays may be gradually increased and then decreased from top to bottom so that a cross-sectional area of an intermediate portion is the largest. In another example embodiment, the cross-sectional areas of nanowires of the vertical nanowire arrays may be gradually decreased and then increased from top to bottom so that a cross-sectional area of an intermediate portion is the smallest.

The cross-sectional areas of nanowires of the vertical nanowire arrays may be circular, triangular, rectangular, or hexagonal.

The upper silicide layer and the lower silicide layer may include at least one of metals such as Co, Ni, Ti, Pt, Al, Ag, Ta, Zn, and In, and silicon.

The first n-type nanowire array and the second n-type nanowire array may be formed such that an n-type doping material is uniformly dispersed in entire nanowires, and the n-type doping material may include P, As, or Sb. In the same manner, the first p-type nanowire array and the second p-type nanowire array may be formed such that a p-type doping material is uniformly dispersed in entire nanowires, and the p-type doping material may include B, BF₂, Al, or Ga.

According to an example embodiment, the vertical nanowire thermoelectric device may further include an insulating material formed on the heat emitting portion to insulate the substrate from the heat emitting portion.

The first upper electrode, the second upper electrode, and the heat emitting portion may be made of a metal having high thermal conductivity and may each include at least one material selected from the group consisting of Pt, Al, Au, Cu, W, Ti, and Cr.

The substrate may be a silicon substrate, a silicon-on-insulator (SOI) substrate, a sapphire substrate, or a glass substrate on which crystalline silicon, polysilicon, amorphous silicon, or a Bi₂Te₃ layer is formed, or may be a bare silicon substrate or a bare SOI substrate.

In other example embodiments, a method of manufacturing a vertical nanowire thermoelectric device, which includes forming of vertical nanowire arrays including a first nanowire array, a second nanowire array, a third nanowire array, and a fourth nanowire array and disposed on a substrate to be spaced apart from each other, doping the vertical nanowire arrays and a substrate region, in which the vertical nanowire arrays are formed, to form a first n-type nanowire array, a first p-type nanowire array, a second n-type nanowire array, a second p-type nanowire array, a first n-type doping region, a first p-type doping region, a second n-type doping region, and a second p-type doping region which respectively correspond to the first n-type nanowire array, the first p-type nanowire array, the second n-type nanowire array, and the second p-type nanowire array, forming an upper silicide layer on nanowires constituting the vertical nanowire arrays, and a lower silicide layer below the first n-type doping region, the second p-type doping region, the first p-type doping region, the second n-type doping region, and the connection region which connects the first p-type doping region and the second n-type doping region, forming a first upper electrode which electrically connects an upper portion of the first n-type nanowire array to an upper portion of the first p-type nanowire array and a second upper electrode which electrically connects an upper portion of the second n-type nanowire array to an upper portion of the second p-type nanowire array, polishing a lower portion of the substrate, and forming a heat emitting portion on the polished lower portion of the substrate.

The method may further include forming a thermal protective film which fills spaces between the vertical nanowire arrays on the substrate after the forming of the upper silicide layer on the nanowires constituting the vertical nanowire arrays, and the lower silicide layer below the first n-type doping region, the second p-type doping region, the first p-type doping region, the second n-type doping region, and the connection region which connects the first p-type doping region and the second n-type doping region.

The forming of the vertical nanowire arrays including the first nanowire array, the second nanowire array, the third nanowire array, and the fourth nanowire array disposed to be spaced apart from each other on the substrate may include forming mask patterns on the substrate, forming the nanowires by performing dry etching on the substrate exposed between the mask patterns, and removing the mask patterns.

The method of manufacturing the vertical nanowire thermoelectric device may further include performing wet etching on the nanowires prior to the removing of the mask pattern after the forming of the nanowires. The surface roughness of the nanowires may be increased.

The doping of the vertical nanowire arrays and the substrate region, in which the vertical nanowire arrays are formed, to form the first n-type nanowire array, the first p-type nanowire array, the second n-type nanowire array, and the second p-type nanowire array, and the first n-type doping region, the first p-type doping region, the second n-type doping region, and the second p-type doping region which respectively correspond to the first n-type nanowire array, the first p-type nanowire array, the second n-type nanowire array, and the second p-type nanowire array may include forming a first protective film on a surface of the substrate and surfaces of the nanowires, forming a first ion implantation preventing film on the first protective film and selectively removing the first ion implantation preventing film on the first n-type doping region and the second n-type doping region, implanting an n-type dopant into a region in which the first ion implantation preventing film is removed so that the first and second n-type doping regions and the first and second n-type nanowire arrays are doped therewith, removing the first ion implantation preventing film, forming a second ion implantation preventing film on the first protective film and selectively removing the second ion implantation preventing film on the first p-type doping region and the second p-type doping region, implanting a p-type dopant into a region in which the second ion implantation preventing film is removed so that the first and second p-type doping regions and the first and second p-type nanowire arrays are doped therewith, removing the second ion implantation preventing film, and removing the first protective film.

Further, the method may further include performing an annealing process prior to the removing of the first protective film after the removing of the second ion implantation preventing film. The dopant may be uniformly dispersed over the entire nanowires without damage to the nanowires.

The n-type dopant or the p-type dopant may be implanted at a concentration of 10¹⁷ cm⁻³ to 10²¹ cm⁻³.

The forming of the upper silicide layer on the nanowires constituting the vertical nanowire arrays and the lower silicide layer below the first n-type doping region, the second p-type doping region, the first p-type doping region, the second n-type doping region, and the connection region which connects the first p-type doping region and the second n-type doping region may include forming a second protective film on the substrate and the vertical nanowire arrays, removing the second protective film on the nanowires constituting the vertical nanowire arrays, the first n-type doping region, the second p-type doping region, the first p-type doping region, the second n-type doping region, and the connection region which connects the first p-type doping region and the second n-type doping region, depositing a metal on a region in which the second protective film and the second protective film are removed, forming the upper silicide layer and the lower silicide layer by annealing process, and removing the residual metal.

The first upper electrode, the second upper electrode, and the heat emitting portion may each include at least one material selected from the group consisting of Pt, Al, Au, Cu, W, Ti, and Cr.

The method may further include depositing an insulating material on the lower portion of the substrate between the polishing of the lower portion of the substrate and the forming of the heat emitting portion on the polished lower portion of the substrate.

### BRIEF DESCRIPTION OF DRAWINGS

Example embodiments of the present invention will become more apparent by describing example embodiments of the present invention in detail with reference to the accompanying drawings, in which:

FIG. 1 is a cross-sectional view showing a vertical nanowire thermoelectric device according to an example embodiment of the present invention;

FIG. 2 shows cross-sectional views showing a method of forming nanowire arrays according to an example embodiment of the present invention;

FIG. 3 shows cross-sectional views showing nanowire arrays according to example embodiments of the present invention, in which top-view shape of nanowires are circular and cross-sectional areas thereof vary;

FIG. 4 shows cross-sectional views showing nanowire arrays according to other example embodiments of the present invention, in which top-view shape of nanowires are triangular and cross-sectional areas thereof vary.

FIGS. 5A and 5B show plan views showing nanowire arrays having various top-view shapes according to example embodiments of the present invention.

FIGS. 6A and 6B show cross-sectional views and plan views showing a method of selectively doping nanowire arrays and a substrate with an n-type dopant and a p-type dopant according to an example embodiment of the present invention;

FIGS. 7A and 7B show cross-sectional views and a plan view showing a method of forming a silicide layer according to an example embodiment of the present invention;

FIG. 8 shows cross-sectional views showing a method of forming a thermal protective film according to an example embodiment of the present invention;

FIG. 9 shows cross-sectional views showing a method of forming upper electrodes according to an example embodiment of the present invention; and

FIG. 10 shows cross-sectional views showing a method of polishing a lower portion of a substrate and forming a heat emitting portion on the polished lower portion of the substrate according to an example embodiment of the present invention.

### DESCRIPTION OF EXAMPLE EMBODIMENTS

While the present invention is susceptible to various modifications and alternative forms, specific embodiments thereof are shown by way of example in the drawings and will herein be described in detail. However, it should be understood that there is no intent to limit the invention to the particular forms disclosed but rather the invention is to cover all modifications, equivalents, and alternatives falling within the spirit and scope of the invention defined by the appended claims.

When an element such as a layer, a region, and a substrate is referred to as being disposed “on” another element, it should be understood that the element may be directly formed thereon or an intervening element may be interposed therebetween.

It should be understood that, although the terms “first,” “second,” etc. may be used herein to describe various elements, components, areas, layers, and/or regions, these elements, components, areas, layers, and/or regions are not limited by these terms.

Hereinafter, exemplary embodiments of the present invention will be described in more detail with reference to the accompanying drawings. Like reference numerals in the drawings denote like elements, and thus the description thereof will not be repeated.

### EXAMPLE EMBODIMENTS

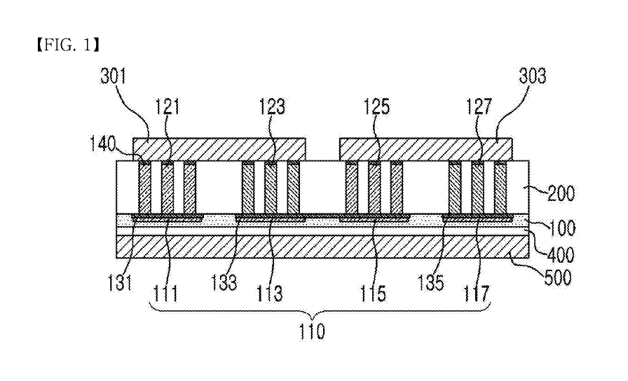

FIG. 1 is a cross-sectional view showing a vertical nanowire thermoelectric device according to an example embodiment of the present invention.

Referring to FIG. 1, the vertical nanowire thermoelectric device according to the example embodiment of the present invention includes a heat emitting portion 500, a substrate 100 above the heat emitting portion 500 adjacent thereto, doping regions 110 including a first n-type doping region 111, a first p-type doping region 113, a second n-type doping region 115, and a second p-type doping region 117 which are sequentially arranged on the substrate 100 to be spaced apart from each other, vertical nanowire arrays 120 including a first n-type vertical nanowire array 121, a first p-type vertical nanowire array 123, a second n-type vertical nanowire array 125, and a second p-type vertical nanowire array 127 which are respectively formed on the first n-type doping region 111, the first p-type doping region 113, the second n-type doping region 115, and the second p-type doping region 117 and include upper and lower silicide layers 130 and 140, a thermal protective film 200 which fills spaces between the vertical nanowire arrays 120, a first upper electrode 301 which is formed on the thermal protective film 200 and electrically connects an upper end of the first n-type nanowire array 121 to an upper end of the first p-type nanowire array 123, a second upper electrode 303 which is formed on the thermal protective film 200 and electrically connects an upper end of the second n-type nanowire array 125 to an upper end of the second p-type nanowire array 127, and a silicide connecting layer 133 which connects the first p-type doping region 113 to the second n-type doping region 115.

In the present example embodiment, the first n-type nanowire array 121, the first p-type nanowire array 123, the second n-type nanowire array 125, and the second p-type nanowire array 127 are sequentially arranged on the substrate 100, but the present invention is not limited thereto. The number of n-type nanowire arrays and p-type nanowire arrays which are arranged in an alternating manner may be increased in order to increase an amount of output of the thermoelectric device.

The heat emitting portion 500 may include a metal having high thermal conductivity. For example, the heat emitting portion 500 may include Pt, Al, Au, Cu, W, Ti, Cr, or an alloy thereof, but the present invention is not limited thereto. The heat emitting portion 500 may allow heat absorbed by the first and second upper electrodes 301 and 303 to pass through the vertical nanowire arrays 120 and be discharged to the outside. In this case, the heat emitting portion 500 may have a structure for increasing a surface area thereof, such as a curve, in order to increase heat emission efficiency.

An insulating material 400 may be selectively formed on the heat emitting portion 500. The insulating material 400 may include at least one of SiO₂, SiN, SOG, borophosphosilicate glass (BPSG), and polyimide.

The substrate 100 is disposed on the heat emitting portion 500. The substrate 100 may be made of any material as long as it can be used as a material of a substrate of a thermoelectric device without limitation. For example, the substrate 100 may be a silicon substrate, a silicon-on-insulator (SOI) substrate, a sapphire substrate, or a glass substrate on which crystalline silicon, polysilicon, amorphous silicon, or a Bi₂Te₃ layer is formed, but the present invention is not limited thereto.

The doping regions 110 are sequentially arranged on the substrate 100 to be spaced apart from each other. The n-type doping regions 121 and 125 and the p-type doping regions 123 and 127 are alternately arranged on the doping regions 110. The n-type doping regions 121 and 125 are formed by uniformly dispersing an n-type dopant in the material forming the substrate. The n-type dopant may include P, As, or Sb. In the same manner, the p-type doping regions 123 and 127 are formed by uniformly dispersing a p-type dopant in the material forming the substrate. The p-type dopant may include B, BF₂, Al, or Ga.

The lower silicide layers 130 may be formed on the doping regions 110 and a region above the substrate 100 in which the first p-type doping region 123 and the second n-type doping region 125 are connected. The silicide layer 133 formed on a connection region in which the first p-type doping region 123 and the second n-type doping region 125 are connected connects the upper electrodes 301 and 303 in series through the first p-type nanowire array 123 and the second n-type nanowire array 125.

The vertical nanowire arrays 120 are formed on the doping regions 110. That is, the vertical nanowire arrays 120 are formed on the lower silicide layers 130. The vertical nanowire arrays 120 have the same conductive type as conductive types of the formed doping regions 110. That is, the vertical nanowire arrays 121 and 125 formed on the n-type doping regions 111 and 115 have an n-type conductive type.

Similar to the doping regions, an n-type dopant or a p-type dopant is uniformly dispersed over the entire nanowires of the vertical nanowire arrays 120. The n-type dopant may include P, As, or Sb, and the p-type dopant may include B, BF₂, Al, or Ga.

Since the vertical nanowire arrays 120 are composed of nanowires arranged in a vertical structure, a density of the nanowires per unit is higher than that in a horizontal nanowire structure. Accordingly, a thermoelectric conversion output and the stability of the thermoelectric device may be increased.

The nanowires constituting the nanowire arrays 120 may have various shapes. As shown in FIG. 1, a shape and area of a cross section may be constant from the top to the bottom of the nanowire. Alternatively, as in other example embodiments which will be described below, a cross-sectional area of a nanowire may gradually increase, decrease, increase and then decrease, or decrease and then increase, from the top to the bottom. Further, the cross section of the nanowire may have various shapes such as a circular shape, a triangular shape, a rectangular shape, and a hexagonal shape, but the present invention is not limited thereto.

Further, upper portions of the nanowires constituting the nanowire arrays 120 are silicidized to form the upper silicide layer 140. The upper silicide layer 140 and the lower silicide layer 130 include silicon silicidized by at least one of metals such as Co, Ni, Ti, Pt, Al, Ag, Ta, Zn, and In.

The upper and lower silicide layers 130 and 140 form Schottky barriers at interfaces between the nanowire arrays 120 and the upper and lower silicide layers 130 and 140. Electrons having energy lower than the Schottky barriers may not freely move along the nanowires, and only electrons having energy higher than the Schottky barriers may move along the nanowires. The electrons that cannot freely move due to an electron filtering effect increase Seebeck voltages of both ends of the nanowire. Further, a metal which is present between silicon lattices due to the silicidation causes phonon scattering in the nanowire, and thus thermal conductivity of the nanowire is reduced. Therefore, the thermoelectric efficiency of the thermoelectric device is improved due to the increase of the Seebeck voltages and the decrease of the thermal conductivity.

The spaces between the nanowires of the nanowire arrays 120 are filled with the thermal protective film 200 so that no empty space is formed between the nanowires. The thermal protective film 200 may be made of a material having low thermal conductivity. For example, the thermal protective film 200 may include SiO₂, SiN, SOG, or BPSG, but the present invention is not limited thereto. The thermal protective film 200 allows thermal energy absorbed by the nanowire arrays 120 to move only through the nanowires without leaking to the outside. Therefore, the consumed heat leaking to the outside may be minimized. The thermal protective film 200 may support the nanowire arrays 120 so that the nanowire arrays 120 are not collapsed due to a subsequent process and physical damage. Further, the thermal protective film 200 may insulate the upper electrodes 301 and 302 from metal electrodes positioned therebelow.

The upper electrodes 301 and 303 are formed to electrically connect the upper portions of the nanowire arrays 120 exposed on the thermal protective film 200. The first upper electrode 301 electrically connects the first n-type nanowire array 121 to the first p-type nanowire array 123, and the second upper electrode 303 electrically connects the second n-type nanowire array 125 to the second p-type nanowire array 127. The first upper electrode 301 and the second upper electrode 303 are connected in series through the silicide layer 133 and the nanowire arrays 120.

The upper electrodes 301 and 303 may include Pt, Al, Au, Cu, W, Ti, Cr, or an alloy thereof. The upper electrodes 301 and 303 transmit heat to upper ends of the vertical nanowire arrays 120 and serve as paths through which a current generated by the thermoelectric conversion flows.

The upper electrodes 301 and 303 may further include an insulating thin film for selective insulation and protection, which is disposed on surfaces thereof.

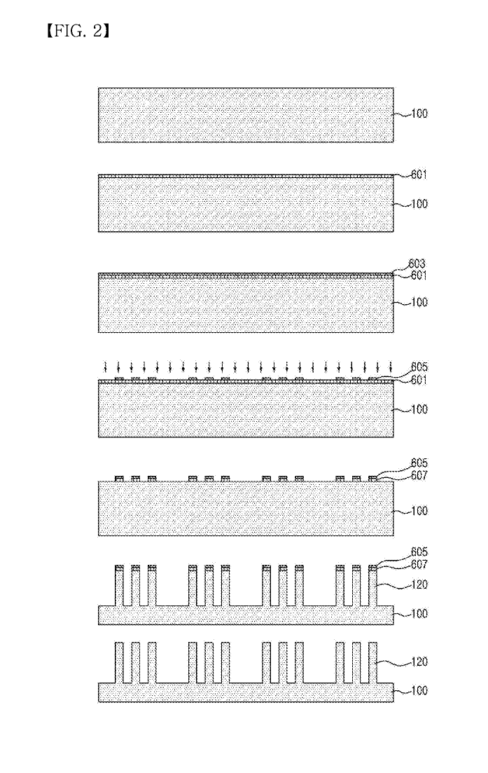

FIG. 2 shows cross-sectional views showing a method of forming nanowire arrays according to an example embodiment of the present invention.

Referring to FIG. 2, first, a substrate 100 is coated with a mask material 601 (S21). Since thermoelectric conversion efficiency increases as a length to diameter ratio of vertical nanowire arrays 120 increases, an etch mask material having high etching selectivity may be used as the mask material 601 in order to form the vertical nanowire arrays 120 having a high length to diameter ratio. An insulating material, such as SiO₂ or SiN, or a metal, such as Al, Cr, Ni, or Ti, may be used as the mask material 601, but the present invention is not limited thereto.

A pattern mask layer 603 for patterning and etching the mask material 601 may be formed on the mask material 601. The pattern mask layer 603 may be patterned using a known nano patterning method such as an electron beam lithography, photolithography, stepper, scanner, or nanoimprint method. Since the thermoelectric conversion efficiency of the thermoelectric device is influenced by a top-view shape of a nanowire, the pattern mask layer 603 may be patterned in various shapes. For example, the pattern mask layer 603 may be patterned in a circular, triangular, rectangular, or hexagonal shape, but the present invention is not limited thereto. The mask material 601 and the substrate 100 are sequentially etched using a patterned pattern mask layer 605 to form the nanowire arrays 120. Only dry etching may be used for forming the vertical nanowire arrays 120, or wet etching and dry etching may be used in combination for etching the mask material 601. Since thermal conductivity of the nanowire is influenced by a shape of a cross-section of the nanowire, a vertical nanowire may be formed in various horizontal cross-section shapes with a constant or non-constant diameter, or horizontal cross-sectional area from the top to the bottom. The horizontal cross-section shape is related to a shape in cross-section in a horizontal direction. The horizontal cross-sectional area is related to cross-sectional area in a horizontal direction.

After the nanowire arrays 120 are formed, the pattern mask layer 605 and a patterned mask material layer 607 are removed.

Since the thermal conductivity of the nanowire is influenced by surface roughness, the method may optionally further include increasing the surface roughness by performing wet etching on the nanowire before the removal of the pattern mask layer 605 and the patterned mask material layer 607.

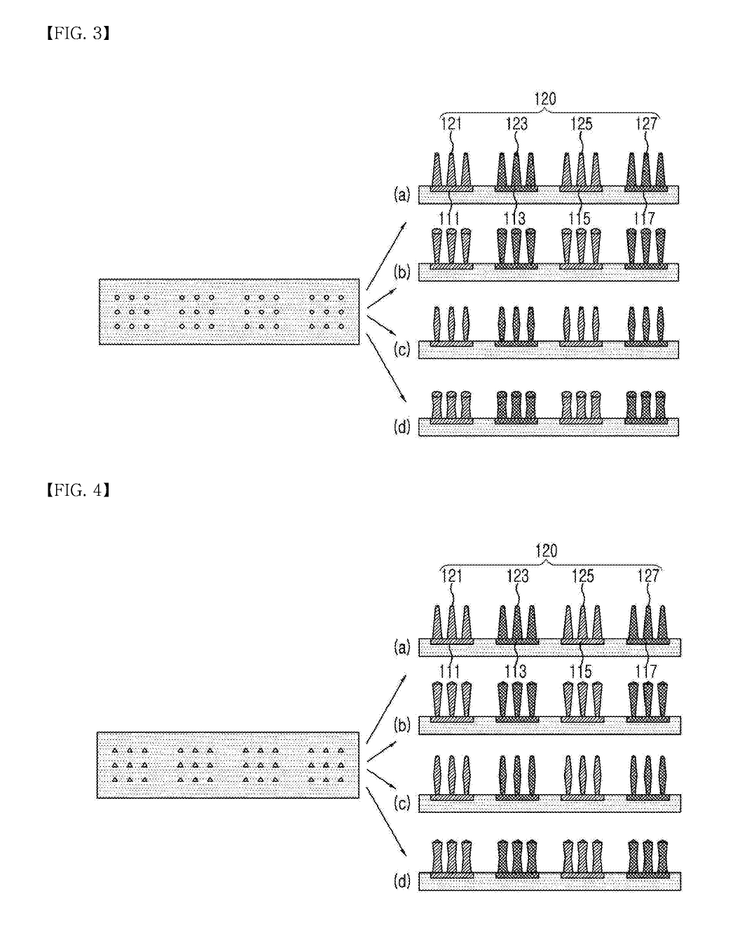

FIG. 3 shows cross-sectional views showing nanowire arrays according to example embodiments of the present invention, in which top-view shape of nanowires are circular and cross-sectional areas thereof vary.

Referring to FIG. 3, even though the top-view shape of the nanowires are equally circular, horizontal cross-sectional diameters of the nanowires may vary according to an etching process. That is, by adjusting conditions of dry etching, the nanowire may be formed in a shape in which a diameter thereof increases from the top to the bottom, as shown in FIG. 3(a), a shape in which a diameter thereof decreases from the top to the bottom, as shown in FIG. 3(b), a jar shape in which a diameter thereof gradually increases and then decreases from the top to the bottom so that an intermediate portion thereof is convex, as shown in FIG. 3(c), and a hourglass shape in which a diameter thereof gradually decreases and then increases from the top to the bottom so that an intermediate portion thereof is concave, as shown in FIG. 3(d).

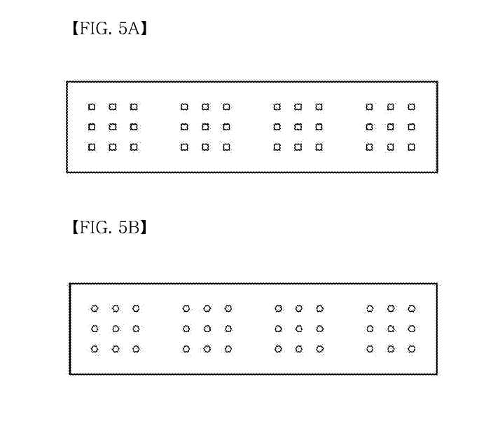

FIG. 4 shows cross-sectional views showing nanowire arrays according to other example embodiments of the present invention, in which top-view shape of nanowires are triangular and vertical cross-sectional areas thereof vary.

Referring to FIG. 4, even though the top-view shape of the nanowires are equal as described in FIG. 3, the vertical cross-sectional areas of the nanowires may vary according to an etching process. The top-view shape of the nanowires may be a triangle, rather than a circle, as shown in FIG. 4.

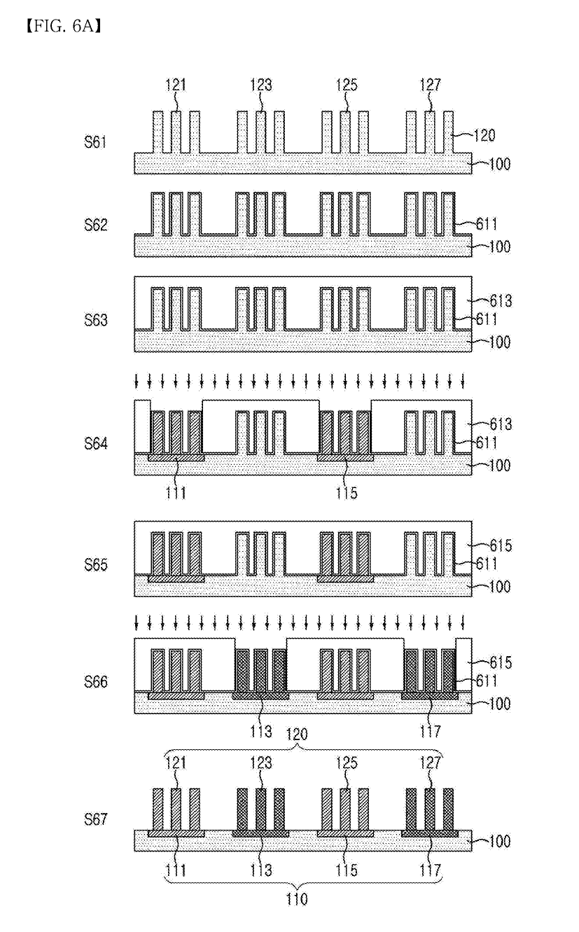

FIG. 5 shows plan views showing nanowire arrays having various top-view shapes according to example embodiments of the present invention.

Referring to FIG. 5, top-view shape of nanowires may have various shapes such as a rectangular shape and a hexagonal shape. Although not described in this specification, various types of figures are applicable without limitation.

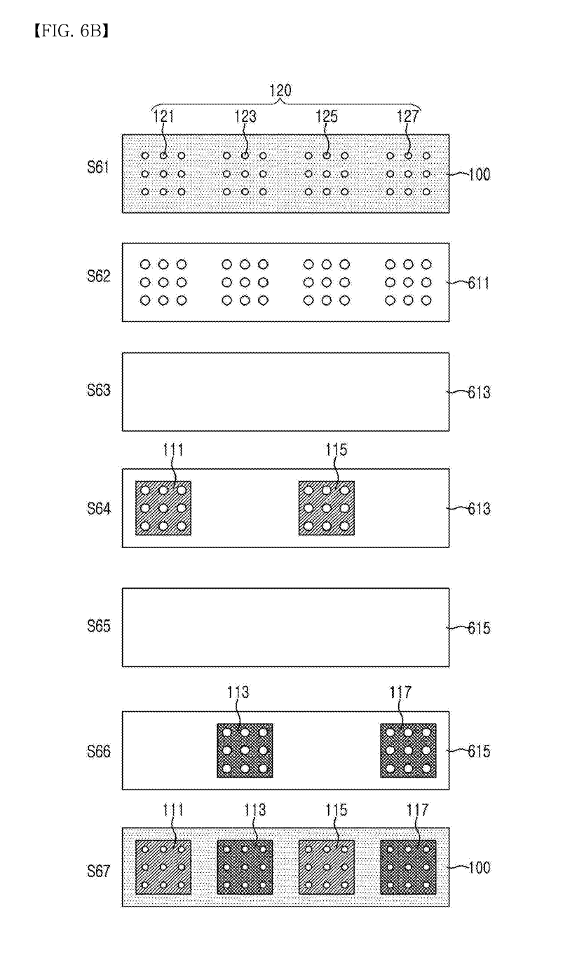

FIGS. 6A and 6B are cross-sectional views and plan views showing a method of selectively doping a nanowire array and a substrate with an n-type dopant and a p-type dopant according to an example embodiment of the present invention.

Referring to FIGS. 6A and 6B, first, a first protective film 611 is deposited on a substrate 100 and nanowire arrays 120 (S62). The first protective film 611 may include SiO₂, SiN, Al₂O₃, or HfO₂. The first protective film 611 prevents damage occurring on surfaces of the silicon substrate 100 and the nanowire arrays 120 during an ion implantation process and prevents impurities from leaking to the outside during an annealing process.

A first ion implantation preventing film 613 is formed on the first protective film 611 (S63). Some regions of the nanowire arrays and the substrate are exposed by removing a portion of the first ion implantation preventing film 613. In this case, only a region of the first ion implantation preventing film 613 in which n-type doping regions 111 and 115 are formed may be removed.

An n-type dopant is implanted into the exposed regions of the nanowire arrays and the substrate (S64). The nanowire arrays and the substrate into which the n-type dopant is implanted become n-type nanowire arrays 121 and 125 and the n-type doping regions 111 and 115, respectively. After the dopant implantation process, the first ion implantation preventing film 613 is removed.

A second ion implantation preventing film 615 is formed on the nanowire arrays 120 and the substrate 100 (S65). Some regions of the nanowire arrays and the substrate 100 are exposed by removing a portion of the second ion implantation preventing film 615. In this case, only a region of the second ion implantation preventing film 615, in which p-type doping regions 113 and 117 are formed, may be removed.

A p-type dopant is implanted into the exposed regions of the nanowire arrays and the substrate 100 (S66). The nanowire arrays and the substrate into which the p-type dopant is implanted become p-type nanowire arrays 123 and 127 and the p-type doping regions 113 and 117, respectively. After the dopant implantation process, the second ion implantation preventing film 615 is removed.

A structure may be formed in which the n-type nanowire arrays 121 and 125 and the p-type nanowire arrays 123 and 127 are alternately and repeatedly arranged using the above-described method (S67). The regions or the orders in which the respective dopants are implanted may vary.

The first ion implantation preventing film 613 and the second ion implantation preventing film 615 may be patterned by a lithography process and an etching process and may be a photoresist, SiO₂, or SiN. In this case, it is easy to remove the ion implantation preventing films 613 and 615 only when a material different from that of the first protective film 611 is used as the ion implantation preventing films 613 and 615.

In the implantation of the n-type dopant and the p-type dopant, an ion implantation method may be used. In this case, in order to uniformly implant impurities into an entirety of the substrate regions and the vertical nanowire arrays, the impurities may be implanted at a specific implantation angle. In this case, the ion implantation angle is calculated based on an interval between vertical nanowires and heights of the vertical nanowires. In this case, the n-type dopant may include P, As, Sb, or the like, and the p-type dopant may include B, BF₂, Al, Ga, or the like. A concentration of the implanted dopant may range from 10¹⁷ cm⁻³ to 10²¹ cm⁻³.

The method may further include performing annealing process for uniformly diffusing a dopant in the entire nanowires after the ion implantation process.

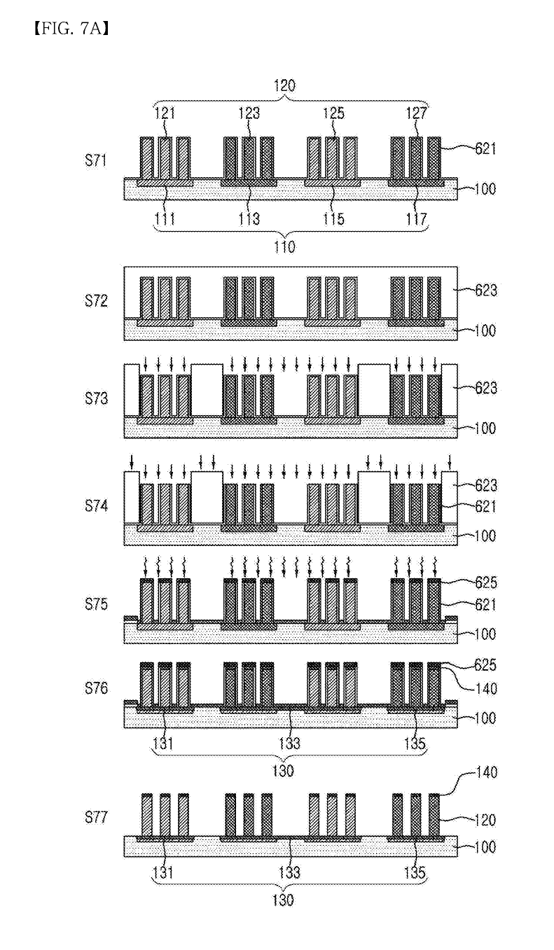

FIGS. 7A and 7B are cross-sectional views and a plan view showing a method of forming a silicide layer according to an example embodiment of the present invention.

Referring to FIG. 7A, first, a second protective film 621 is formed on the nanowire arrays 120 and the substrate 100 (S71). The second protective film 621 may be a thin film for preventing silicide formation and may be SiO₂, SiN, a high-k insulating film, or a polymer. The second protective film 621 is formed to sufficiently protect side surfaces of the nanowire arrays 120.

A patterning mask layer 623 is formed on the second protective film 621 (S72). The patterning mask layer 623 is selectively etched to expose doping regions 110 and a connection region for connecting the first p-type doping region 113 and the second n-type doping region 115 (S73).

The second protective film 621 in a region not covered by the patterning mask layer 623 is selectively etched (S74). In this case, by adjusting conditions of an etching process, the second protective film 621 which surrounds the side surfaces of the nanowires remains, and only the second protective film 621 formed on upper surfaces of the nanowires and the doping regions 110 may be selectively etched. The patterning mask layer 623 is then removed.

A metal is deposited on the substrate 100 and the nanowire arrays 120 (625), and silicide layers 130 and 140 are formed by annealing process (S75). The metal may be deposited using a known deposition method without limitation.

Residual metals which do not react with silicon and the second protective film 621 are removed. The residual metals may be removed using sulfuric acid and hydrogen peroxide. In this case, the method may optionally include forming a metal electrode on the silicide layer 133 formed in the connection region which connects the first p-type doping region 113 and the second n-type doping region 115 in order to reduce the resistance of the thermoelectric device.

FIG. 7B is a plan view showing a positional relationship between the nanowire arrays 120 and a lower silicide layer 130. The lower silicide layers 130 may be formed in the region in which the nanowire arrays 120 are formed and the connection region which connects the first p-type doping region 113 and the second n-type doping region 115.

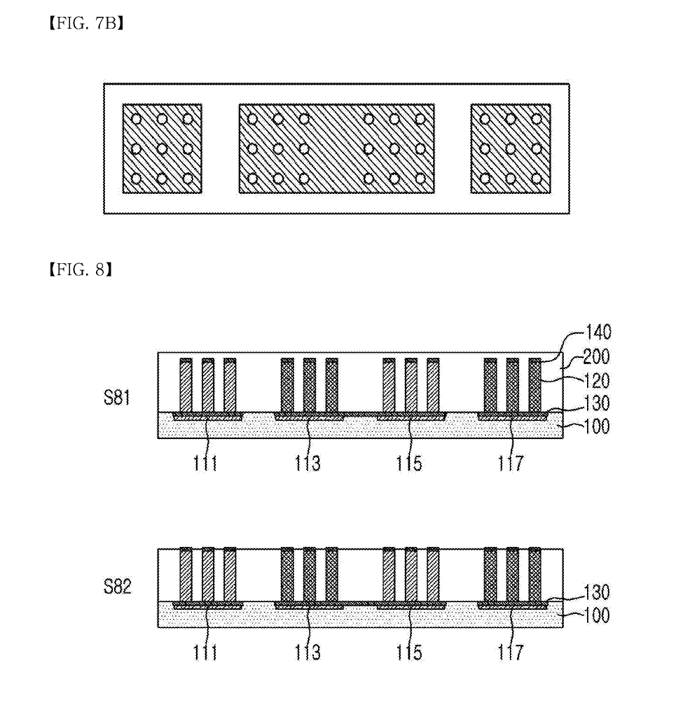

FIG. 8 shows cross-sectional views showing a method of forming a thermal protective film according to an example embodiment of the present invention.

Referring to FIG. 8, first, a thermal protective film 200 material is applied so as to fill spaces between vertical nanowire arrays 120 (S81). The thermal protective film 200 material is sufficiently applied so that no empty space is formed between the vertical nanowire arrays 120.

Thereafter, an upper portion of the thermal protective film 200 is etched so that the silicide layer 140 is exposed (S82).

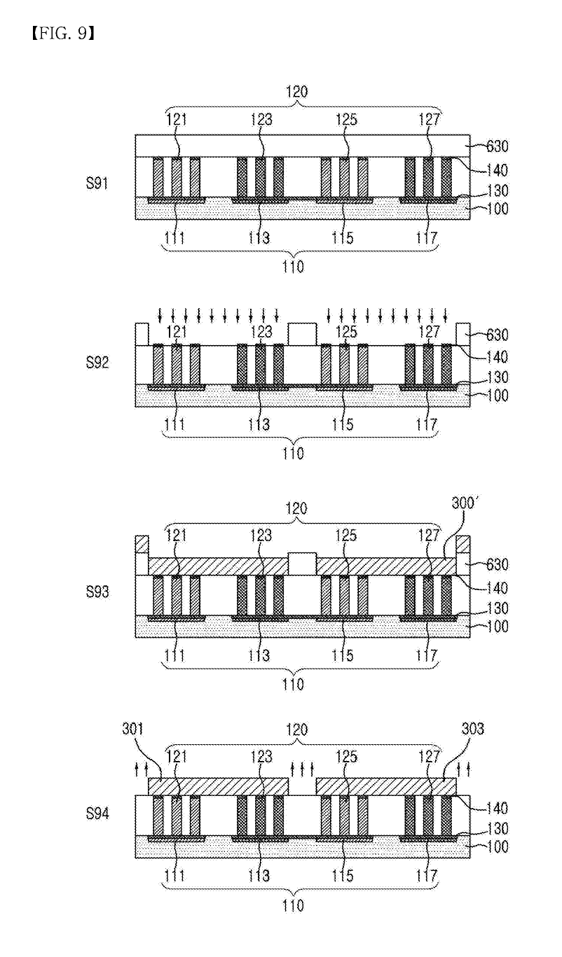

FIG. 9 shows cross-sectional views showing a method of forming upper electrodes according to an example embodiment of the present invention.

Referring to FIG. 9, first, a mask material 630 is formed onto the thermal protective film 200 (S91). The mask material 630 over the upper portions of the first n-type nanowire array 121 and the first p-type nanowire array 123, the region which connects the first n-type nanowire array 121 and the first p-type nanowire array 123, the upper portions of the second n-type nanowire array 125 and the second p-type nanowire array 127, and the region which connects the second n-type nanowire array 125 and the second p-type nanowire array 127 are removed using a lithography process (S92).

A metal 300′ is deposited on the mask material 630 and the thermal protective film 200 (S93). In this case, an insulating material thin film for insulation and protection of the metal electrode may be selectively formed on the metal material 300′.

A first upper electrode 301 and a second upper electrode 303 are formed by removing the mask material 630 (S94). Unlike the example embodiment described with reference to the present drawing, according to another example embodiment of the present invention, the upper electrodes 301 and 303 may be formed by wet etching. When the upper electrodes 301 and 303 are formed by the wet etching, the metal 300′ is deposited first, and then a mask material pattern is formed on the metal. Thereafter, the metal in regions except for the regions in which the upper electrodes are formed may be removed by performing wet etching using the mask material pattern so that the upper electrodes 301 and 303 may be formed. Optionally, an insulating material thin film for insulation and protection of the metal electrode may be formed on the metal surface.

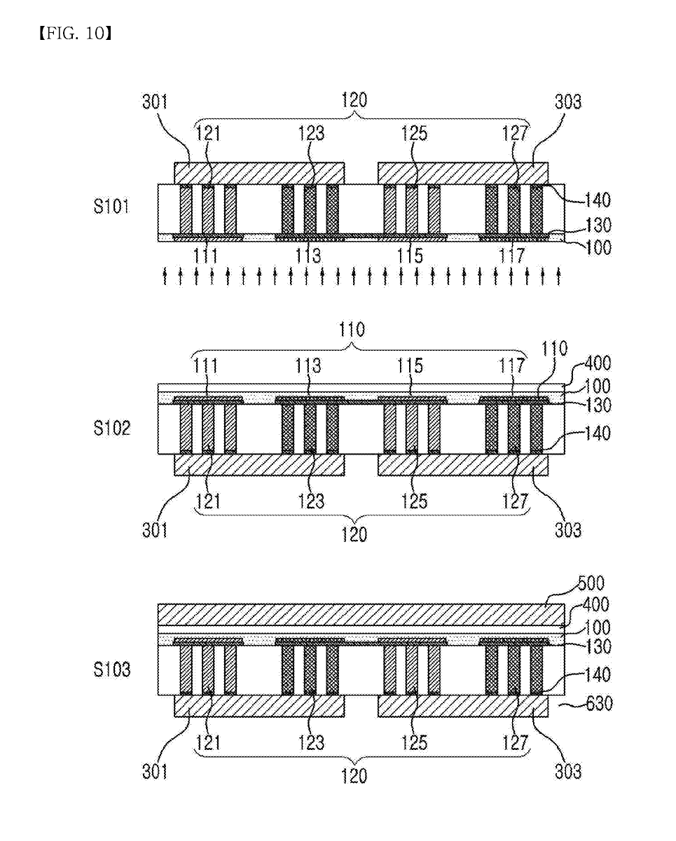

FIG. 10 shows cross-sectional views showing a method of polishing a lower portion of a substrate and forming a heat emitting portion on the polished lower portion of the substrate according to an example embodiment of the present invention.

Referring to FIG. 10, first, a lower region of the substrate 100 is removed by polishing the lower portion of a substrate 100 on which the nanowire arrays 120 and the upper electrode structures 301 and 303 are formed (S101). In order to remove the lower portion of the substrate 100, a dry etching process or a wet etching process may be used as well as the semiconductor polishing process. Since the lower region of the substrate 100 has low electrical conductivity and high thermal conductivity, an amount of electricity generated by thermoelectric conversion is reduced and an amount of electricity consumed due to high resistance is increased. Therefore, the characteristics of the thermoelectric device may be improved by removing the lower region of the substrate 100.

An insulating material 400 may be selectively deposited to insulate the polished lower portion of the substrate 100 (S102).

A heat emitting portion 500 made of a metal having high thermal conductivity is formed on the insulating material 400 (S103). In this case, the heat emitting portion 500 may have a structure for increasing a surface area thereof in order to increase the heat emission efficiency.

According to the present invention, in a vertical nanowire thermoelectric device including a silicide layer, silicide layers can be formed above and below nanowires to prevent phonon movement in the nanowire, thereby lowering thermal conductivity and improving a Seebeck effect. This can result in higher thermoelectric conversion efficiency and an increased amount of output than conventional silicon nanowire thermoelectric devices.

In addition, a thermal protective film having low thermal conductivity fills spaces between the nanowires so that thermal energy received by heating the thermoelectric device is moved only through silicon nanowires. Accordingly, an amount of thermal energy transmitted to vertical silicon nanowires can be increased.

In the vertical nanowire thermoelectric device including the silicide layer, it is possible to mass-produce devices by manufacturing the vertical nanowire thermoelectric device using a semiconductor process, and it is possible to lower the unit cost of the device by using a silicon material as a main material. Accordingly, the vertical nanowire thermoelectric device according to the present invention and the method of manufacturing the same are advantageous for commercialization.

Effects of the present invention are not limited to the above-described effects and other unmentioned effects may be clearly understood by those skilled in the art from the above detailed descriptions.

Meanwhile, the embodiments disclosed in this specification and drawings are only examples for the sake of understanding and the invention is not limited thereto. It is clear to those skilled in the art that various modifications based on the technological scope of the invention in addition to the embodiments disclosed herein can be made. For example, the forming of the vertical nanowire arrays and the doping of the vertical nanowire arrays may be performed in reverse order.

### REFERENCE NUMERALS

100: SUBSTRATE
110: DOPING REGIONS
120: NANOWIRE ARRAYS
130: LOWER SILICIDE LAYER
140: UPPER SILICIDE LAYER
200: THERMAL PROTECTIVE FILM
300: UPPER ELECTRODES

What is claimed is:

1. A vertical nanowire thermoelectric device comprising:
a heat emitting portion;
a substrate disposed on the heat emitting portion and including doping regions having a first n-type doping region, a first p-type doping region, a second n-type doping region, and a second p-type doping region which are arranged to be spaced apart from each other;
vertical nanowire arrays including a first n-type nanowire array, a first p-type nanowire array, a second n-type nanowire array, and a second p-type nanowire array which are formed on the first n-type doping region, the first p-type doping region, the second n-type doping region, and the second p-type doping region, respectively;
a lower silicide layer formed in the doping regions and a connection region which connects the first p-type doping region and the second n-type doping region;
an upper silicide layer formed on the vertical nanowire arrays;
a first upper electrode configured to electrically connect an upper end of the first n-type nanowire array to an upper end of the first p-type nanowire array; and
a second upper electrode configured to electrically connect an upper end of the second n-type nanowire array to an upper end of the second p-type nanowire array.

2. The vertical nanowire thermoelectric device of claim 1, further comprising a thermal protective film formed on the substrate and configured to fill spaces between the vertical nanowire arrays.

3. The vertical nanowire thermoelectric device of claim 2, wherein the thermal protective film is made of at least one of SiO₂, SiN, SOG, borophosphosilicate glass (BPSG), and polyimide.

4. The vertical nanowire thermoelectric device of claim 1, wherein the vertical nanowire arrays include nanowires having a shape in which a cross section is constant from top to bottom.

5. The vertical nanowire thermoelectric device of claim 1, wherein the vertical nanowire arrays have nanowires having inclined side surfaces because horizontal cross-sectional areas of upper portions of the nanowires are greater or smaller than horizontal cross-sectional areas of lower portions of the nanowires.

6. The vertical nanowire thermoelectric device of claim 1, wherein horizontal cross-sectional areas of nanowires of the vertical nanowire arrays are gradually increased and then decreased from top to bottom so that a cross-sectional area of an intermediate portion is the largest.

7. The vertical nanowire thermoelectric device of claim 1, wherein horizontal cross-sectional areas of nanowires of the vertical nanowire arrays are gradually decreased and then increased from top to bottom so that a cross-sectional area of an intermediate portion is the smallest.

8. The vertical nanowire thermoelectric device of claim 1, wherein top-view shapes of nanowires of the vertical nanowire arrays are circular, triangular, rectangular, or hexagonal.

9. The vertical nanowire thermoelectric device of claim 1, wherein the upper silicide layer and the lower silicide layer include at least one of metals such as Co, Ni, Ti, Pt, Al, Ag, Ta, Zn, and In, and silicon.

10. The vertical nanowire thermoelectric device of claim 1, wherein:
the first n-type nanowire array and the second n-type nanowire array are formed such that an n-type doping material is uniformly dispersed in entire nanowires; and
the n-type doping material includes P, As, or Sb.

11. The vertical nanowire thermoelectric device of claim 1, wherein:
the first p-type nanowire array and the second p-type nanowire array are formed such that a p-type doping material is uniformly dispersed in entire nanowires; and
the p-type doping material includes B, BF₂, Al, or Ga.

12. The vertical nanowire thermoelectric device of claim 1, further comprising an insulating material formed on the heat emitting portion to insulate the substrate from the heat emitting portion.

13. The vertical nanowire thermoelectric device of claim 1, wherein the first upper electrode, the second upper electrode, and the heat emitting portion each include at least one material selected from the group consisting of Pt, Al, Au, Cu, W, Ti, and Cr.

14. The vertical nanowire thermoelectric device of claim 1, wherein the substrate is a silicon substrate, a silicon-on-insulator (SOI) substrate, a sapphire substrate, or a glass substrate on which crystalline silicon, polysilicon, amorphous silicon, or a Bi₂Te₃ layer is formed, or is a bare silicon substrate or a bare SOI substrate.

15. A method of manufacturing a vertical nanowire thermoelectric device, the method comprising:
forming vertical nanowire arrays including a first nanowire array, a second nanowire array, a third nanowire array, and a fourth nanowire array disposed to be spaced apart from each other on a substrate;
doping the vertical nanowire arrays and a substrate region, in which the vertical nanowire arrays are formed, to form a first n-type nanowire array, a first p-type nanowire array, a second n-type nanowire array, a second p-type nanowire array, and doping regions including a first n-type doping region, a first p-type doping region, a second n-type doping region, and a second p-type doping region which respectively correspond to the first n-type nanowire array, the first p-type nanowire array, the second n-type nanowire array, and the second p-type nanowire array;
forming an upper silicide layer on nanowires constituting the vertical nanowire arrays, a lower silicide layer below the doping regions, and a connection region which connects the first p-type doping region to the second n-type doping region;
forming a first upper electrode which electrically connects an upper portion of the first n-type nanowire array to an upper portion of the first p-type nanowire array and a second upper electrode which electrically connects an upper portion of the second n-type nanowire array to an upper portion of the second p-type nanowire array;
polishing a lower portion of the substrate; and
forming a heat emitting portion on the polished lower portion of the substrate.

16. The method of claim 15, further comprising forming a thermal protective film which fills spaces between the vertical nanowire arrays on the substrate after the forming of the upper silicide layer on the nanowires constituting the vertical nanowire arrays, and the lower silicide layer below the first n-type doping region, the second p-type doping region, the first p-type doping region, the second n-type doping region, and the connection region which connects the first p-type doping region and the second n-type doping region.

17. The method of claim 15, wherein the forming of the vertical nanowire arrays including the first nanowire array, the second nanowire array, the third nanowire array, and the fourth nanowire array disposed to be spaced apart from each other includes on the substrate:
forming mask patterns on the substrate;
forming the vertical nanowire arrays by performing dry etching on the substrate exposed between the mask patterns; and
removing the mask patterns.

18. The method of claim 17, further comprising performing wet etching on the vertical nanowire arrays prior to the removing of the mask pattern after the forming of the vertical nanowire arrays.

19. The method of claim 15, wherein the doping of the vertical nanowire arrays and the substrate region, in which the vertical nanowire arrays are formed, to form the first n-type nanowire array, the first p-type nanowire array, the second n-type nanowire array, the second p-type nanowire array, and the doping regions including the first n-type doping region, the first p-type doping region, the second n-type doping region, and the second p-type doping region which respectively correspond to the first n-type nanowire array, the first p-type nanowire array, the second n-type nanowire array, and the second p-type nanowire array includes:
forming a first protective film on a surface of the substrate and surfaces of the vertical nanowire arrays;
forming a first ion implantation preventing film on the first protective film and selectively removing the first ion implantation preventing film on the first n-type doping region and the second n-type doping region;
implanting an n-type dopant into a region in which the first ion implantation preventing film is removed so that the first and second n-type doping regions and the first and second n-type nanowire arrays are doped therewith;
removing the first ion implantation preventing film;
forming a second ion implantation preventing film on the first protective film and selectively removing the second ion implantation preventing film on the first p-type doping region and the second p-type doping region;
implanting a p-type dopant into a region in which the second ion implantation preventing film is removed so that the first and second p-type doping regions and the first and second p-type nanowire arrays are doped therewith;
removing the second ion implantation preventing film; and
removing the first protective film.

20. The method of claim 19, further comprising performing an annealing process prior to the removing of the first protective film after the removing of the second ion implantation preventing film.

21. The method of claim 19, wherein the n-type dopant or the p-type dopant is implanted at a concentration of 10¹⁷ cm⁻³ to 10²¹ cm⁻³.

22. The method of claim 15, wherein the forming of the upper silicide layer on the nanowires constituting the vertical nanowire arrays, and the lower silicide layer below the doping regions and the connection region which connects the first p-type doping region to the second n-type doping region includes:
forming a second protective film on the substrate and the vertical nanowire arrays;
removing the second protective film on the nanowires constituting the vertical nanowire arrays, the doping regions, and the connection region which connects the first p-type doping region to the second n-type doping region;
depositing a metal on a region in which the second protective film and the second protective film are removed;
forming the upper silicide layer and the lower silicide layer by annealing process; and
removing the residual metal.

23. The method of claim 15, wherein the first upper electrode, the second upper electrode, and the heat emitting portion each include at least one material selected from the group consisting of Pt, Al, Au, Cu, W, Ti, and Cr.

24. The method of claim 15, further comprising depositing an insulating material on the lower portion of the substrate between the polishing of the lower portion of the substrate and the forming of the heat emitting portion on the polished lower portion of the substrate.
